(19) United States
(12) Patent Application Publication
(10) Pub. No.: US 2020/0013533 A1
(43) Pub. Date: Jan. 9, 2020

(54) MAGNETIC SOLDER MASK ON PACKAGE SUBSTRATE ABOVE MAGNETIC INDUCTOR ARRAY

(71) Applicant: Intel Corporation, Santa Clara, CA (US)

(72) Inventors: Malavarayan SANKARASUBRAMANIAN, Chandler, AZ (US); Anne AUGUSTINE, Chandler, AZ (US); Yongki MIN, Phoenix, AZ (US); Kaladhar RADHAKRISHNAN, Chandler, AZ (US)

(73) Assignee: Intel Corporation, Santa Clara, CA (US)

(21) Appl. No.: 16/026,401

(22) Filed: Jul. 3, 2018

(51) Int. Cl. H01F 17/04; H01L 23/00; H01F 27/28

(52) U.S. Cl. CPC H01F 17/04; H01L 24/16; H01L 2924/19106; H01L 2224/16265; H01L 2924/19042; H01F 27/2823

(57) ABSTRACT

A microelectronics package, comprising a substrate that comprises a dielectric and an inductor component comprising one or more wires within a magnetic core over the dielectric. The inductor component is bonded to the substrate by one or more solder joints. A solder mask is between the inductor component and the dielectric. The one or more solder joints are surrounded by the solder mask, and wherein the solder mask comprises a magnetic material.

### BACKGROUND

Integrated voltage regulator (IVR) technology is an efficient die and package architecture for managing disparate voltages required by the various functions encompassed by a microprocessor. Currently, IVR implementations in microprocessor packages, such as fully-integrated voltage regulator (FIVR) topologies, rely on air-core inductors. Typically, the air-core inductors are off-die, either on, or embedded within, the package dielectric adjacent to the microprocessor die. Industry trends and market pressures are forcing chip manufacturers to reduce package footprint with succeeding microprocessor generations. Space for the embedded inductor is reduced as well, causing decreases in inductor performance. In particular, the successively more compact air-core inductors have inductances that diminish from generation to generation, resulting in declining quality factor (ratio of energy stored in the inductor's magnetic field to energy dissipated by resistive losses in the inductor windings). As a consequence, the overall efficiency of IVRs suffer as losses increase.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1A illustrates a cross-sectional view in the y-z plane showing a magnetic inductor array (MIA) component solder-bonded to a package substrate with an intervening magnetic solder mask, according to some embodiments of the disclosure.

FIG. 1B illustrates a cross-sectional view in the x-z plane showing a MIA component solder bonded to a package substrate with an intervening magnetic solder mask, according to some embodiments of the disclosure.

FIG. 1C illustrates a plan view in the x-y plane showing a MIA component over a package substrate with an intervening magnetic solder mask, according to some embodiments of the disclosure.

FIG. 2A-2K illustrate an exemplary method for forming a magnetic solder mask between a MIA component and a package substrate, according to some embodiments of the disclosure.

FIG. 3 illustrates a flow chart summarizing the method for forming a magnetic solder mask between a MIA component and a package substrate, as illustrated in FIGS. 2A-2K, according to some embodiments of the disclosure.

FIG. 4 illustrates a package fabricated according to the disclosed methods, having a MIA component attached to a package substrate, with a magnetic solder mask in between the MIA and the substrate, as part of a system-on-chip (SoC) package in an implementation of computing device, according to some embodiments of the disclosure.

### DETAILED DESCRIPTION

In the following description, numerous details are discussed to provide a more thorough explanation of embodiments of the present disclosure. It will be apparent, however, to one skilled in the art, that embodiments of the present disclosure may be practiced without these specific details. In other instances, well-known structures and devices are shown in block diagram form, rather than in detail, in order to avoid obscuring embodiments of the present disclosure.

The innovation disclosed herein is a novel magnetic inductor array (MIA) that addresses the concerns introduced above. In contrast to lithographically-defined inductors that are fabricated by patterning conductive layers within cored or coreless build-up package architectures, the novel inductors are discrete MIAs that are assembled onto package substrates by solder bonding.

According to some embodiments, the MIA is an inductive component that is manufactured separately from the package substrate to which the MIA is to be attached. In some architecture embodiments of the instant innovation, a MIA component comprises multiple parallel inductors, which comprise conductors extending between opposing contact pads. In some embodiments, the multiple parallel inductor arrangement of the MIA component enables parallel coupling of individual inductors to enhance current carrying capacity for large current delivery. as well as inductance of the inductor. MIAs also provide individual inductors that are coupled to separate voltage regulator (e.g., IVR) circuits.

The MIA component is generally attached to the land side of a package substrate. In some embodiments, a package substrate may be fully or partially assembled by build-up processes to form conductive signal routing layers and via interconnects between conductive layers, interspersed with dielectric layers. At a specific package layer, a MIA is solder-bonded to bondpads on the land side of the package substrate. The package layer at which this operation is performed may be the top conductive layer on the land side of the substrate.

To facilitate the solder bonding process, a patterned solder mask is deposited on the landside of a package substrate to form solder balls over bondpads in an array of bondpads on the package substrate. The solder mask is patterned to have openings over the bondpads. Solder paste or liquid is then deposited within the openings within the solder mask to form solder balls. A conventional solder mask comprises a non-magnetic dielectric material. A MIA component may then be attached to the package substrate by solder bonding to the land side.

The thickness, or z-height, of the MIA is restricted as land grid array (LGA) becomes increasingly smaller. Package height requirements further restrict the z-height of the MIA component. A reduction in the thickness of the magnetic core reduces the inductance density of the MIA component. The reduction of the inductance density degrades the effectiveness of the MIA component, where the quality factor (Q) of the inductors is reduced. The Q of an inductor is a figure of merit concerning the ratio of the energy stored in the inductor's magnetic field to the energy dissipated by the resistance of the inductor. In buck converter voltage regulation topologies, which is commonly employed in IVRs, reduced Q results in lower efficiencies and reduced ability to filter residual ripple voltage from the direct current output of the IVR device.

According to embodiments of the innovation, the thickness reduction of the native magnetic core of the MIA may be compensated by deposition of a solder mask comprising magnetic material comparable to the magnetic material in the MIA core over the package substrate before attachment of the MIA component. The magnetic solder mask forms an external magnetic layer of a desired thickness between the native magnetic core of the MIA component and the package dielectric. Accordingly, the magnetic solder mask effectively extends the thickness of the native magnetic core of the MIA, enabling a higher inductance density within the MIA, hence a higher performance voltage regulation device.

Throughout the specification, and in the claims, the term “connected” or “interconnected” means a direct connection, such as electrical, mechanical, or magnetic connection between the things that are connected, without any intermediary devices.

Here, the term “coupled” means a direct or indirect connection, such as a direct electrical, mechanical, or magnetic connection between the things that are connected or an indirect connection, through one or more passive or active intermediary devices.

Here, the term “package” generally refers to a self-contained carrier of one or more dies, where the dies are attached to the package substrate, and encapsulated for protection, with integrated or wire-boned interconnects between the die(s) and leads, pins or bumps located on the external portions of the package substrate. The package may contain a single die, or multiple dies, providing a specific function. The package is usually mounted on a printed circuit board for interconnection with other packaged ICs and discrete components, forming a larger circuit.

Here, the term “substrate” refers to the substrate of an IC package. The package substrate is generally coupled to the die or dies contained within the package, where the substrate comprises a dielectric having conductive structures on or embedded with the dielectric. Throughout this specification, the term “package substrate” is used to refer to the substrate of an IC package.

Here, the term “core” generally refers to a stiffening layer generally embedded within of the package substrate, or comprising the base of a package substrate. In many IC package architectures, a core may or may not be present within the package substrate. A package substrate comprising a core is referred to as a “cored substrate”. A package substrate is generally referred to as a “coreless substrate”. The core may comprise a dielectric organic or inorganic material, and may have conductive vias extending through the body of the core. In instances where the description mentions a package or package substrate, “package core” will be used to refer to the core.

The term “core” may also refer to a magnetic core. In instances where the description mentions an inductor, “magnetic core” will be used to to avoid confusion with references to a package core.

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The term “microprocessor” generally refers to an integrated circuit (IC) package comprising a central processing unit (CPU) or microcontroller. The microprocessor package may comprise a land grid array (LGA) of electrical contacts, and an integrated heat spreader (IHS). The microprocessor package is referred to as a “microprocessor” in this disclosure. A microprocessor socket receives the microprocessor and couples it electrically to the PCB.

The vertical orientation is in the z-direction and it is understood that recitations of “top”, “bottom”, “above” and “below” refer to relative positions in the z-dimension with the usual meaning. However, it is understood that embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional”, “profile”, “plan”, and “isometric” correspond to orthogonal planes within a cartesian coordinate system. Thus, cross-sectional and profile views are taken in the x-z plane, plan views are taken in the x-y plane, and isometric views are taken in a 3-dimensional cartesian coordinate system (x-y-z). Where appropriate, drawings are labeled with axes to indicate the orientation of the figure.

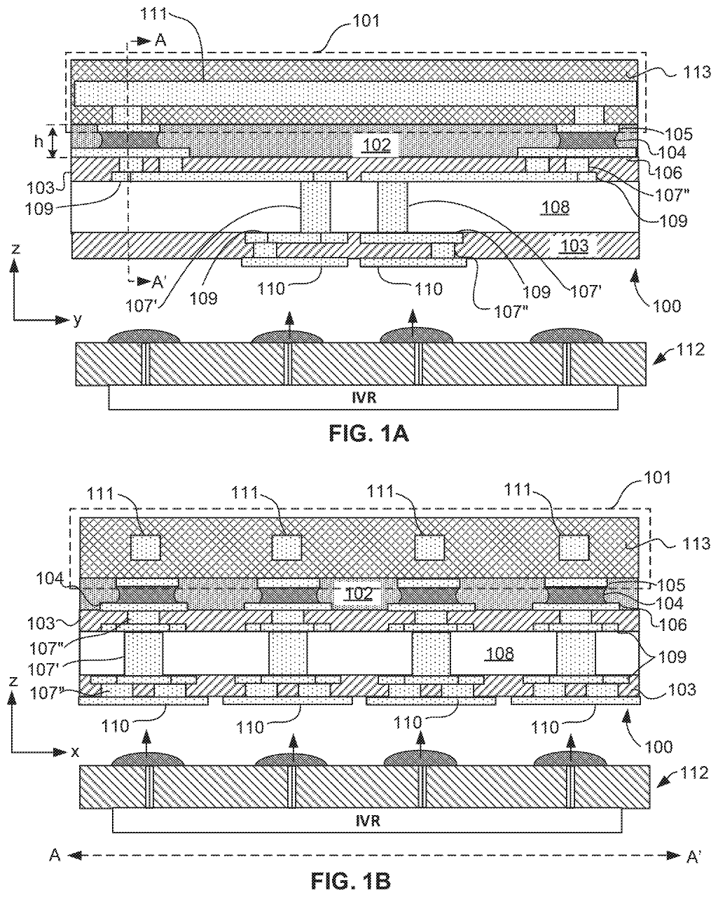

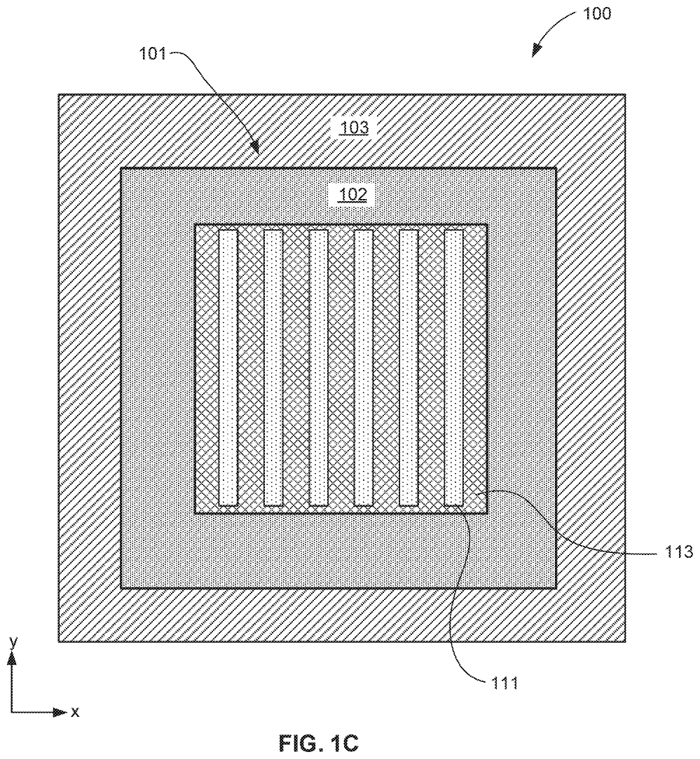

FIG. 1A illustrates a cross-sectional view in the y-z plane showing MIA component 101 solder-bonded to package substrate 100 with an intervening magnetic solder mask, according to some embodiments of the disclosure.

In FIG. 1A, a cross-sectional view of MIA component 101 attached to the land side of package substrate 100 is shown. Here, the orientation of package substrate 100 is inverted from the normal view where the die side is above the land side. MIA component 101 is a discrete component that is separate from package substrate 100. In some embodiments, MIA component 101 comprises one or more inductors 111 extending through native magnetic core 113. Magnetic solder mask 102 intervenes between MIA 101 and package dielectric 103. Solder joints 104 are between MIA pads 105 and package land side bondpads 106. In some embodiments, magnetic solder mask 102 surrounds or embeds solder joints 104. Magnetic solder mask comprises a magnetic material that is described below.

In the illustrated embodiment, package substrate 100 is a cored substrate, where package dielectric 103 is over package core 108. In some embodiments, bondpads 106 are in a top conductive layer on the land side of package substrate 100. MIA 101 extends over (in the z-direction) package dielectric 103.

In the illustrated embodiments, package substrate 100 comprises a single build-up film laminate layer (e.g., package dielectric 103) over core 108. In some embodiments, multiple film layers comprising a suitable package dielectric material may be laminated one at a time over a rigid package core to form a stack of overlaid laminates of package dielectric. For formation of cored package substrates, package core 108 is a rigid component upon which the substrate is built.

An example is a package substrate formed by bumpless build-up layer (BBUL) methodology. The term “bumpless” refers to dielectric layers of substrate and components and conductive structures embedded within the dielectric layers, where no solder balls or bumps are used as means of attachment.

In some embodiments, package dielectric 103 comprises composite epoxies, liquid crystalline polymers, polyamides or polyimides. Other suitable package dielectric materials may be used. In some embodiments, package dielectric 103 comprises dielectric film laminate layers having thicknesses ranging from 20 to 40 microns. In some embodiments, all layers have the same thickness. In some embodiments, variable thickness dielectric film laminate layers may be overlaid. In some embodiments, overlaid laminate films have different thicknesses, as shown in the illustrated embodiment of FIG. 1A. As several laminates may be overlaid, package dielectric 103 has a thickness that ranges from 100 to 1500 microns.

Conductive layers may be formed over each dielectric layer. Vias may interconnect conductive layers. Through-vias 107′ extend through package core 108 to couple conductive structures on one side of package core 108 to conductive structures on the opposite side of package core 108. A first conductive layer comprising traces 109 is over package core 108. Vias 107″ extend through dielectric 103 on both sides of package core 108 and couple traces 109 to bondpads 106 on the land side of package substrate 100 and to bondpads 110 on the opposing die side of package substrate 100. In the illustrated embodiment, dielectric 103 comprises a single laminate layer. In some embodiments, dielectric 103 comprises multiple laminate layers. Conductive structures (e.g., bondpads 106 and 110, traces 109 and vias 107′ and 107″) comprise any of copper, gold, silver, molybdenum or tungsten. In general, conductive structures are formed by electroplating or electroless deposition methods. An example of an electrodeposition method is described below.

Embedded conductive layers (e.g., traces 109) are at the boundary between laminate dielectric layers, including package core 108. Vias 107′ convey signals from the land side of package substrate 100 to higher conductive layers (e.g., toward the die side of package substrate 100). Signals may also be routed within embedded conductive layers through traces 109.

In some embodiments, an inductor loop is formed by a signal path formed by a MIA inductor 111 coupled to a trace 109 through a first (left in the figure) via 107″ on the land side of package core 108. The signal path continues to follow a first through-via 107′ extending through package core 108 (on the left side in the figure) and conveying the signal loop therethrough. On the opposite (die) side of package core 108, the signal loop continues, and is conveyed by a second via(s) 107″ to die side bondpad 110. The inductor loop continues through an IVR on attached die 112, which interconnects first and second bondpads 110.

The inductor loop continues through a second via(s) 107″ on the right side of the figure, which couple bondpad 110 to trace 109. A second through-via 107′ (right side of the figure) returns the signal path to the land side of package substrate 100, where the inductor loop exits package substrate 100 through a second bondpad 106 (on the right side of the figure) to the right side of inductor 111, competing the inductor loop.

In some embodiments, magnetic solder mask 102 has a thickness (z-height) h ranging between 15 and 30 microns. In some embodiments, MIA 101 extends to a z-height of up to 220 microns over package dielectric 103.

The inductance density is a function of the permeability of the magnetic core material in MIA 101 and the number of inductors 111 within MIA 101. A MIA is a discrete inductive component that is attached to the land side of a package substrate. In many implementations, a MIA is coupled to voltage regulation circuitry (e.g., an integrated voltage regulator, IVR) on an attached microprocessor die. Hence, a thicker native magnetic core (typically 220 microns) is required for the MIA to have sufficient inductance density. MIA thickness may be reduced below the optimal value, magnetic solder mask 102 effectively increases the MIA native thickness.

In some embodiments, magnetic solder mask 102 comprises a finely-divided magnetic material within a neutral (non-magnetic, non-conductive) matrix. In some embodiments, the matrix is a thermoplastic or thermosetting organic polymer comprising epoxy resins, polyamide resins, polyimide resins, polysulfones. Inorganic materials such as silica filler, silicates, may also be included.

Suitable finely-divided magnetic materials include, but are not limited to, any of iron, nickel, nickel-iron alloys such as Mu metals and/or permalloys. In some embodiments, magnetic materials comprise lanthanide and/or actinide elements. In some embodiments, magnetic solder mask 102 comprises cobalt-zirconium-tantalum alloy (e.g., CZT). Suitable magnetic materials may also comprise semiconducting or semi-metallic Heusler compounds and non-conducting (ceramic) ferrites. In some embodiments, ferrite materials comprise any of nickel, manganese, zinc, and/or cobalt cations, in addition to iron. In some embodiments, ferrite materials comprise barium and/or strontium cations. Heusler compounds may comprise any of manganese, iron, cobalt, molybdenum, nickel, copper, vanadium, indium, aluminum, gallium, silicon, germanium, tin, and/or antimony. Heusler alloy, Co, Fe, Ni, Gd, B, Ge, Ga, permalloy, or Yttrium Iron Garnet (YIG), and wherein the Heusler alloy is a material which includes one or more of: Cu, Mn, Al, In, Sn, Ni, Sb, Ga, Co, Fe, Si, Pd, Sb, V, Ru, Cu2MnAl, Cu2MnIn, Cu2MnSn, Ni2MnAl, Ni2MnIn, Ni2MnSn, Ni2MnSb, Ni2MnGa Co2MnAl, Co2MnSi, Co2MnGa, Co2MnGe, Pd2MnAl, Pd2MnIn, Pd2MnSn, Pd2MnSb, Co2FeSi, Co2FeAl, Fe2VAl, Mn2VGa, Co2FeGe, MnGa, MnGaRu, or Mn3X, where ‘X’ is one of Ga or Ge.

Materials such as Pt, Pd, W, Ce, Al, Li, Mg, Na, Cr2O3, CoO, Dy, Dy2O, Er, Er2O3, Eu, Eu2O3, Gd, Gd2O3, FeO, Fe2O3, Nd, Nd2O3, KO2, Pr, Sm, Sm2O3, Tb, Tb2O3, Tm, Tm2O3, V, V2O3 or epoxy material with particles of a magnetic alloy. A magnetic alloy can be an alloy formed of one or more of: Pt, Pd, W, Ce, Al, Li, Mg, Na, Cr, Co, Dy, Er, Eu, Gd, Fe, Nd, K, Pr, Sm, Tb, Tm, or V.

In some embodiments, magnetic solder mask 102 has a relative permeability ranging between 5 and 20.

FIG. 1B illustrates a cross-sectional view in the x-z plane showing MIA 101 solder bonded to package substrate 100 with an intervening magnetic solder mask, according to some embodiments of the disclosure.

In FIG. 1B, the profile view is taken along plane A-A′ in FIG. 1A, and is rotated 90° from the cross-sectional view of FIG. 1A. MIA component 101 is shown in cross section, where multiple individual inductors 111 extend in a parallel orientation through native magnetic core 113. Within the body of MIA component 101, individual inductors are separate and not physically coupled, according to some embodiments. In some embodiments, each inductor 111 within MIA component 101 is electrically coupled in parallel to a single signal source externally to MIA component 101 through package substrate 100.

In some embodiments, the signal sources are integrated voltage regulators (IVRs) that are on a die 112 attached to package substrate 100. When in use, current is supplied as pulsed direct current (dc). Typical pulse frequencies are above 100 MHz, and may formed by switching transistors coupled to the input side of MIA component 101.

In some embodiments, MIA component 101 has an inductance ranging between 2 and 4 nanohenries (nH). The particular value of inductance depends on the dimensions of inductors 111 and the relative permeability of native magnetic core 113. A parallel inductor topology where multiple wirebond inductors 101 are coupled in parallel to a single signal source in general may have a smaller inductance than any of the individual inductors coupled in parallel. Inductors may be coupled in parallel to handle currents that are too large to be handled safely by any individual inductor. For parallel topologies, the inductance of the individual inductors may be adjusted by choice of length and cross-sectional dimensions to maintain a self-inductance for each inductor.

In some embodiments, MIA component 101 has an overall inductance ranging between 2.5 and 4 nH, depending on the number of inductors 111 conducting current, size of the current, and the physical size and relative permeability of native magnetic core 113. The overall inductance is the combined self-inductance and mutual inductance for inductors 111 within the body of MIA component 101. The inductance density of the MIA component is the inductance per unit volume. Thus, decreasing the z-height for a given footprint (form factor in the x-y plane) negatively impacts the inductance density, and the overall inductance of the MIA inductor.

Magnetic solder mask 102 effectively adds z-height to native magnetic core 113. In some embodiments, the relative magnetic permeability of magnetic solder mask 102 ranges between 5 and 20. The magnetic permeability may be adjusted by choice of magnetic particles in terms of particle size, concentration and the relative permeability of the magnetic particles.

In some embodiments, magnetic solder mask 102 comprises a magnetic material that is substantially the same as the magnetic material comprised by native magnetic core 113 of MIA component 101. In some embodiments, magnetic solder mask 102 comprises a magnetic material that is different than the magnetic material of native magnetic core 113. In some embodiments, magnetic solder mask 102 comprises a magnetic material that is compositionally different from the magnetic material of native magnetic core 113, but has a relative magnetic permeability that is substantially the same as the relative magnetic permeability of native magnetic core 113. In some embodiments, magnetic solder mask 104 comprises a magnetic material that has a larger relative magnetic permeability than that of native magnetic core 113. For the latter case, the thickness of magnetic solder mask 102 may be less than the thickness of a magnetic solder mask having a relative magnetic permeability that is the same or less than that of native magnetic core 113.

As an example, the addition of magnetic solder mask 102 having a thickness of 25 microns between MIA component 101 and package substrate 103, the inductance of the individual inductors 111 within MIA component 101 increases by approximately 10% over a conventional (non-magnetic) solder mask. For a given MIA component 101, the inductance increases from approximately 2.4 nH to approximately 2.65 nH by the inclusion of a 25 micron layer of magnetic solder mask 104. The Q factor increases from approximately 14 to approximately 14.2 as the resistance is substantially unaffected. The higher Q affords higher overall efficiency for the IVRs to which MIA component 101 is coupled.

In some implementations, individual inductors 111 within MIA component 101 are coupled independently to IVR circuitry. As an example, inductors 111 are coupled to independent switching transistor pairs in buck regulator circuits, generating pulsed dc currents that are phased. Each inductor 111 carries a radio frequency (if) current of 140 MHz, differentially phased, to a load circuit in the IVR. Load shunt capacitance in the IVR circuitry is coupled to each inductor 111, and together the relatively high self-inductance value of inductor 111, filters the current to reduce the pulses to a relatively low value of ripple (e.g., 20%) superimposed on a pure dc component.

In some embodiments, the IVR circuitry comprises a boost converter topology. In some embodiments, the IVR circuitry comprises a buck/boost converter topology. In some embodiments, the IVR circuitry comprises a flyback converter topology.

The amount of ripple voltage or current may be reduced to a suitable predetermined level by choice of the value of self-inductance of inductors 111, and shunt capacitance values. For any self-inductance value of inductors 111 (mostly determined by the length of the inductor 111 and relative magnetic permeability of native magnetic core 113), dissipative losses the resistance of the bondwire are compensated by the relatively high inductance density, increasing the Q of inductors 111 over that of a typical MIA. The proximity of the parallel inductors 111 within native magnetic core 113 permit a high level of magnetic coupling between the inductors 111, as current may be flowing in the same direction through each inductor 111.

Inductance density within MIA component 101 is also enhanced by the parallel arrangement and close proximity of the inductors 111. Current flowing in the same direction in each inductor 111 enable positive mutual inductance to add to the self-inductance of the individual inductors 111. The combination of a high mutual inductance and self-inductance inductors 111 enable a high inductance density for MIA component 101.

FIG. 1C illustrates a plan view in the x-y plane showing MIA component 101 over package substrate 100 with an intervening magnetic solder mask, according to some embodiments of the disclosure.

FIG. 1C shows MIA component 101 comprising inductors 111 and native magnetic core 113 is shown on the die side of package substrate 100. In some embodiments, magnetic solder mask 102 exceeds the borders of MIA component 101, as shown in FIG. 1C. In some embodiments, magnetic solder mask 102 is confined to the extent of MIA component 101. Magnetic solder mask 102 may exceed the extent of MIA component 101 to provide a solder mask to bondpads that are used for attaching to a motherboard or other substrate. The increase in inductance of MIA component 101 that is afforded by the addition of magnetic solder mask 102 is not significantly affected by the lateral extent of magnetic solder mask 102.

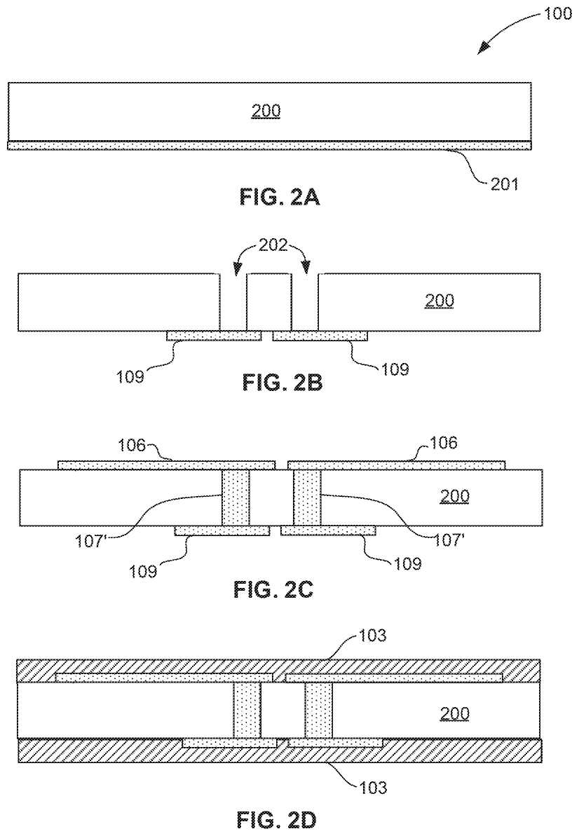

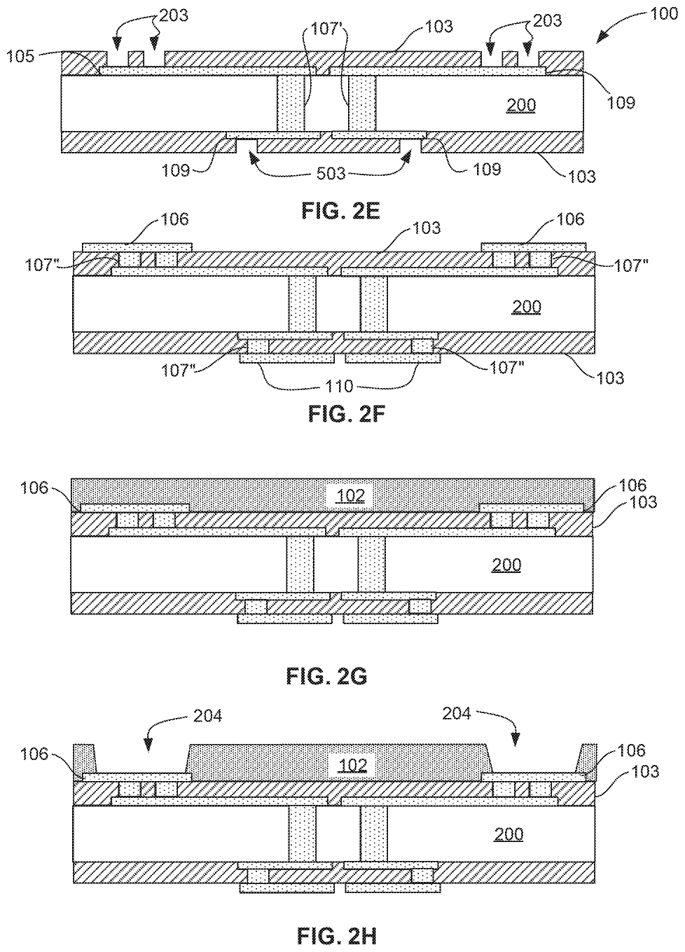

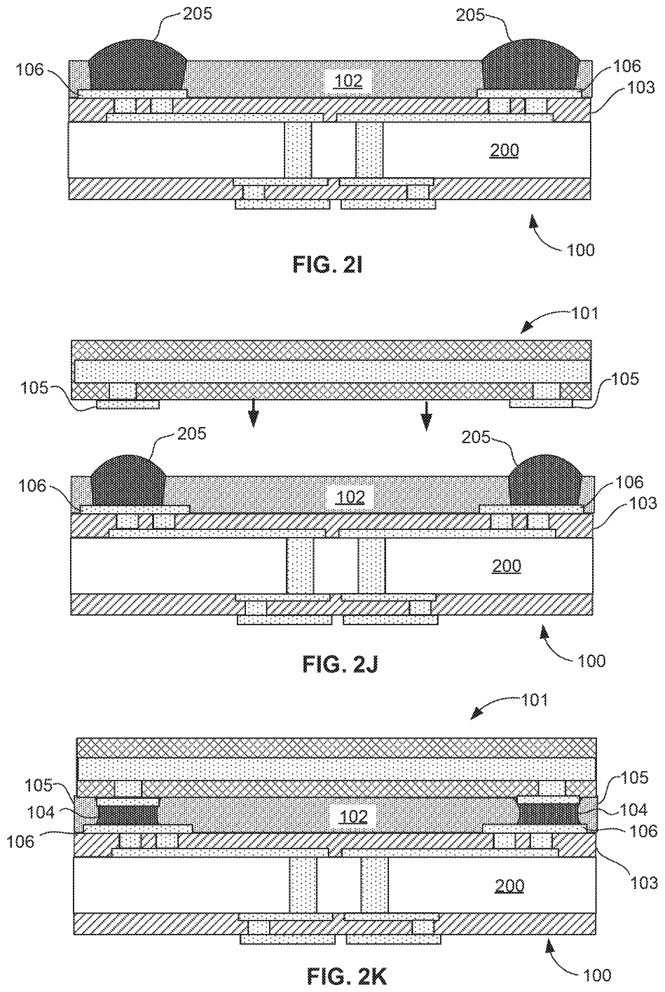

FIGS. 2A-2K illustrate an exemplary method for forming magnetic solder mask 102 between MIA component 101 and package substrate 100, according to some embodiments of the disclosure.

In the operation shown in FIG. 2A, package core 500 is received in an early stage of preparation. In some embodiments, package core 500 comprises a plated copper layer 501 on at least one side. Package core 500 has a thickness ranging between 100 and 500 microns. In some embodiments, copper layer 501 has a thickness ranging between 15 to 35 microns.

In the operation shown in FIG. 2B, copper layer 501 is patterned to form conductive structures (e.g., traces 109). In some embodiments, traces 109 are formed by lithographic methods. A photoresist etching mask may be deposited over copper layer 501, through which copper layer 501 is patterned by wet etch methods to form traces 109. In some embodiments, dry etching methods may be employed to form traces 109.

Holes 502 may be formed in package core 500 either before or after formation of traces 109. In some embodiments, holes 502 are formed by drilling methods. In some embodiments, holes 502 are formed by laser drilling, where infrared lasers such as carbon dioxide (CO₂) or neodymium-doped yttrium aluminum garnet (Nd:YAG) lasers are employed to ablate package core 500. The copper layer is not damaged when the laser penetrates through package core 500, and performs as a laser stop. Typically, laser-drilled holes are conical due to the radial gaussian distribution of laser energy.

In the operation shown in FIG. 2C, through-vias 107′ and traces 109 are formed by electroplating copper into holes 502. In some embodiments, a conductive seed layer is deposited over package core 500, which provides an electrode surface and performs as a conformal plating cathode. Through-vias 107′ interconnect conductive structures on both sides of package core 500, and have a z-height that is the same or exceeds slightly the thickness of package core 500. In some embodiments, conductive structures such as traces 109 comprise copper having a thickness ranging between 15 microns and 35 microns. Traces 109 form a first conducive layer within package substrate 100.

In the operation shown in FIG. 2D, dielectric layers 103 are laminated conformally over both sides of package core 500 and traces 109. Any suitable lamination method may be employed to form dielectric layers 103. In some embodiments, dielectric film layers 103 have thicknesses ranging from 20 to 40 microns. In some embodiments, dielectric film layers comprise polymer sheets composed of epoxies, polyimides or polyamides.

In the operation shown in FIG. 2E, holes 503 are formed in dielectric film layers 103 on both sides of package core 500. Holes 503 are formed in preparation of electrodeposition of through-vias 107′ through dielectric layers 103. Holes 503 are openings exposing portions of traces 109, which provide conductive electrode surfaces on which to initiate electroplating. In some embodiments, holes 503 are formed by laser drilling as described above.

In the operation shown in FIG. 2F, a second conductive layer comprising bondpads 106 and 110, as well as vias 107″ that interconnect intermediate traces 109 with surface bondpads 106 and 110, are formed over both dielectric layers 103 on each side of package core 500. In some embodiments, bondpads 106 and 110 are formed by electroplating a sheet of copper and patterning, as described above. In some embodiments, bondpads 106 are on the land side of package substrate 100, and bondpads 110 are on the die side of package substrate 500.

In the operation shown in FIG. 2G, magnetic solder mask 102 is deposited over package dielectric 103 and bondpads 106. Magnetic solder mask 102 may be deposited by any suitable method, including, but not limited to, spin coating, spray coating and lamination.

In the operation shown in FIG. 2H, openings 204 are made in magnetic solder mask 102 over bondpads 106. Methods to make the openings include photolithographic methods and laser drilling techniques.

In the operation shown in FIG. 2I, solder bumps 205 are deposited in openings 204 in magnetic solder mask 102. Any suitable method may be employed to form solder bumps 205. In some embodiments, solder bumps 205 are formed by printing solder paste over openings 204 in magnetic solder mask 102.

In the operation shown in FIG. 2J, MIA component 101 is positioned over package substrate 100 in preparation for attachment to bondpads 106. In some embodiments, MIA component 101 is positioned by a pick-and-place operation to align bondpads 105 on MIA component 101 with solder bumps 205 over bondpads 106.

In the operation shown in FIG. 2K, solder is reflowed to form solder joints 104, bonding MIA component 101 to package substrate 100 through solder joints between bondpads 106 on the land side of package substrate 100 and bondpads 105 on MIA component 101.

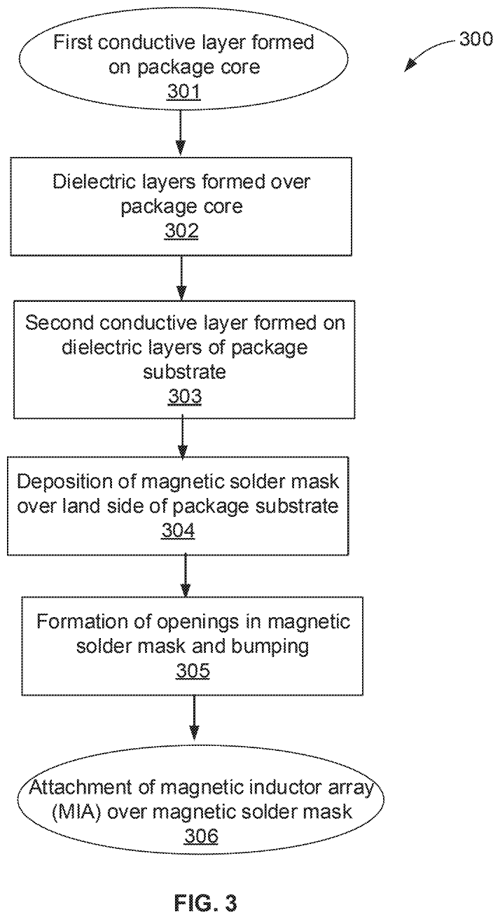

FIG. 3 illustrates flow chart 300 summarizing the method for forming magnetic solder mask 102 between MIA component 101 and package substrate 100, as illustrated in FIGS. 2A-2K, according to some embodiments of the disclosure.

At operation 301, a first conductive layer is formed over both sides of a package core (e.g., package core 200). A layer of copper may be electroplated over each side of a fiberglass or glass package core. The copper layer may be patterned by lithographic techniques. In some embodiments, an etch mask is formed over the copper layer by depositing a photoresist and forming a negative pattern. The copper may be etched by wet etch methods through openings in the photoresist mask to form conductive structures such as traces 105.

Holes are made in the package core in preparation of deposition of through-vias (e.g., through-vias 107′) extending through package core 200. Laser drilling methods may be employed to form holes in the package core.

At operation 302, dielectric layers are deposited over copper structures on each side of the package core. In some embodiments, dielectric layers are epoxy (or other polymers) laminate films used in build-up package assembly. Suitable lamination methods may be employed.

At operation 303, a second conductive layer is formed over the dielectric layers formed in the previous operation. In some embodiments, the conductive layer is formed from electroplated copper. Vias (e.g., vias 107″) are formed during this step. Prior to electrodeposition of the copper layer, holes may be formed in the dielectric layer over traces 105 where vias are to be formed.

A conductive seed layer may be deposited over the dielectric layers and into the holes formed in the dielectric prior to the copper electrodeposition operation. Vias 107″ and a copper layer are deposited to form the second conductive layer in the holes and over the dielectric layers on both sides of the package core. The second copper layer is than patterned to form conductive structures such as bondpads 104 on the land side and 106 on the die side. The package substrate (e.g., package substrate 100) is completed.

At operation 304, the magnetic solder mask (e.g., magnetic solder mask 102) is deposited on the land side of the package substrate over the package dielectric and land side bondpads. Any suitable deposition process may be employed, such as spin coating, printing or lamination.

At operation 305, openings are formed in the magnetic solder mask over land side bondpads that are to be coupled to a MIA component. Openings may be formed by lithographic methods or by laser drilling. After formation of the openings, solder paste may be printed into the openings over the bondpads.

At operation 306, a MIA (e.g., MIA component 101) is positioned over the magnetic solder mask, where bondpads on the MIA component are aligned with solder bumps on the package substrate. A suitable pick-and-place operation may be employed to perform the attachment operation. When the MIA component is in place, solder joints are formed between the bondpads on the MIA and the land side bondpads on the package substrate by a reflow process. The magnetic solder mask is in between the MIA and the package dielectric.

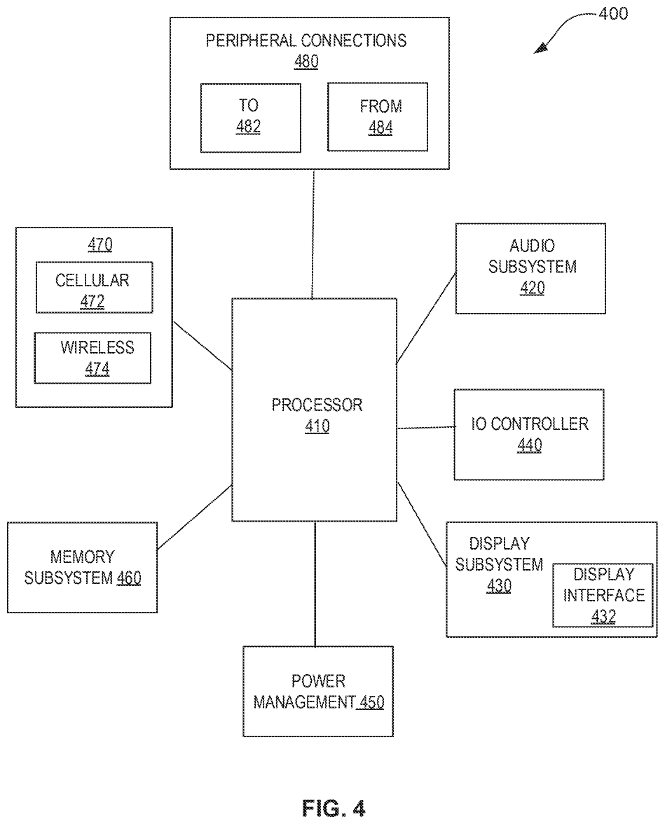

FIG. 4 illustrates a package fabricated according to the disclosed methods, having a MIA component (e.g. MIA component 101) attached to package substrate 100, with magnetic solder mask 102 between, as part of a system-on-chip (SoC) package in an implementation of computing device, according to some embodiments of the disclosure.

FIG. 4 illustrates a block diagram of an embodiment of a mobile device in which a magnetic inductor array (e.g., MIA component 101) is attached to a microprocessor package substrate. A magnetic solder mask is between the MIA and the dielectric of the package substrate. In some embodiments, computing device 400 represents a mobile computing device, such as a computing tablet, a mobile phone or smart-phone, a wireless-enabled e-reader, or other wireless mobile device. It will be understood that certain components are shown generally, and not all components of such a device are shown in computing device 400.

In some embodiments, computing device 400 includes a first processor 410 that comprises at least one FIVR. The various embodiments of the present disclosure may also comprise a network interface within 470 such as a wireless interface so that a system embodiment may be incorporated into a wireless device, for example, cell phone or personal digital assistant.

In one embodiment, processor 410 can include one or more physical devices, such as microprocessors, application processors, microcontrollers, programmable logic devices, or other processing means. The processing operations performed by processor 410 include the execution of an operating platform or operating system on which applications and/or device functions are executed. The processing operations include operations related to I/O (input/output) with a human user or with other devices, operations related to power management, and/or operations related to connecting the computing device 400 to another device. The processing operations may also include operations related to audio I/O and/or display I/O.

In one embodiment, computing device 400 includes audio subsystem 420, which represents hardware (e.g., audio hardware and audio circuits) and software (e.g., drivers, codecs) components associated with providing audio functions to the computing device. Audio functions can include speaker and/or headphone output, as well as microphone input. Devices for such functions can be integrated into computing device 400, or connected to the computing device 400. In one embodiment, a user interacts with the computing device 400 by providing audio commands that are received and processed by processor 410.

Display subsystem 430 represents hardware (e.g., display devices) and software (e.g., drivers) components that provide a visual and/or tactile display for a user to interact with the computing device 400. Display subsystem 430 includes display interface 432 which includes the particular screen or hardware device used to provide a display to a user. In one embodiment, display interface 432 includes logic separate from processor 410 to perform at least some processing related to the display. In one embodiment, display subsystem 430 includes a touch screen (or touch pad) device that provides both output and input to a user.

I/O controller 440 represents hardware devices and software components related to interaction with a user. I/O controller 440 is operable to manage hardware that is part of audio subsystem 420 and/or display subsystem 430. Additionally, I/O controller 440 illustrates a connection point for additional devices that connect to computing device 400 through which a user might interact with the system. For example, devices that can be attached to the computing device 400 might include microphone devices, speaker or stereo systems, video systems or other display devices, keyboard or keypad devices, or other I/O devices for use with specific applications such as card readers or other devices.

As mentioned above, I/O controller 440 can interact with audio subsystem 420 and/or display subsystem 430. For example, input through a microphone or other audio device can provide input or commands for one or more applications or functions of the computing device 400. Additionally, audio output can be provided instead of, or in addition to display output. In another example, if display subsystem 430 includes a touch screen, the display device also acts as an input device, which can be at least partially managed by I/O controller 440. There can also be additional buttons or switches on the computing device 400 to provide I/O functions managed by I/O controller 440.

In one embodiment, I/O controller 440 manages devices such as accelerometers, cameras, light sensors or other environmental sensors, or other hardware that can be included in the computing device 400. The input can be part of direct user interaction, as well as providing environmental input to the system to influence its operations (such as filtering for noise, adjusting displays for brightness detection, applying a flash for a camera, or other features).

In one embodiment, computing device 400 includes power management 450 that manages battery power usage, charging of the battery, and features related to power saving operation. Memory subsystem 460 includes memory devices for storing information in computing device 400. Memory can include nonvolatile (state does not change if power to the memory device is interrupted) and/or volatile (state is indeterminate if power to the memory device is interrupted) memory devices. Memory subsystem 460 can store application data, user data, music, photos, documents, or other data, as well as system data (whether long-term or temporary) related to the execution of the applications and functions of the computing device 400.

Elements of embodiments are also provided as a machine-readable medium (e.g., memory 460) for storing the computer-executable instructions. The machine-readable medium (e.g., memory 460) may include, but is not limited to, flash memory, optical disks, CD-ROMs, DVD ROMs, RAMs, EPROMs, EEPROMs, magnetic or optical cards, phase change memory (PCM), or other types of machine-readable media suitable for storing electronic or computer-executable instructions. For example, embodiments of the disclosure may be downloaded as a computer program (e.g., BIOS) which may be transferred from a remote computer (e.g., a server) to a requesting computer (e.g., a client) by way of data signals via a communication link (e.g., a modem or network connection).

Connectivity via network interface 470 includes hardware devices (e.g., wireless and/or wired connectors and communication hardware) and software components (e.g., drivers, protocol stacks) to enable the computing device 400 to communicate with external devices. The computing device 400 could be separate devices, such as other computing devices, wireless access points or base stations, as well as peripherals such as headsets, printers, or other devices.

Network interface 470 can include multiple different types of connectivity. To generalize, the computing device 400 is illustrated with cellular connectivity 472 and wireless connectivity 474. Cellular connectivity 472 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, or other cellular service standards. Wireless connectivity (or wireless interface) 474 refers to wireless connectivity that is not cellular, and can include personal area networks (such as Bluetooth, Near Field, etc.), local area networks (such as Wi-Fi), and/or wide area networks (such as WiMax), or other wireless communication.

Peripheral connections 480 include hardware interfaces and connectors, as well as software components (e.g., drivers, protocol stacks) to make peripheral connections. It will be understood that the computing device 400 could both be a peripheral device (“to” 482) to other computing devices, as well as have peripheral devices (“from” 484) connected to it. The computing device 400 commonly has a “docking” connector to connect to other computing devices for purposes such as managing (e.g., downloading and/or uploading, changing, synchronizing) content on computing device 400. Additionally, a docking connector can allow computing device 400 to connect to certain peripherals that allow the computing device 400 to control content output, for example, to audiovisual or other systems.

In addition to a proprietary docking connector or other proprietary connection hardware, the computing device 400 can make peripheral connections 480 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other types.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional element.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

We claim:

1. A microelectronics package, comprising:
a substrate comprising a dielectric;
an inductor component comprising one or more wires within a magnetic core over the dielectric, wherein the inductor component is bonded to the substrate by one or more solder joints; and
a solder mask between the inductor component and the dielectric, wherein the one or more solder joints are surrounded by the solder mask, and wherein the solder mask comprises a magnetic material.

2. The microelectronics package of claim 1, wherein the inductor comprises one or more wires extending substantially parallel to one another within the magnetic core.

3. The microelectronics package of claim 1, wherein the magnetic core comprises magnetic particles in a dielectric matrix.

4. The microelectronics package of claim 3, wherein the magnetic particles comprise any one of iron, nickel, cobalt, manganese, samarium, ytterbium, gadolinium, terbium, or dysprosium.

5. The microelectronics package of claim 3, wherein the dielectric matrix comprises an epoxy resin or an acrylic resin.

6. The microelectronics package of claim 1, wherein the magnetic material of the solder mask comprises any one of any one of iron, nickel, cobalt, manganese, a lanthanide element or an actinide element.

7. The microelectronics package of claim 1, wherein the solder mask comprises a polymer matrix.

8. The microelectronics package of claim 7, wherein the polymer matrix comprises an epoxy resin, a polyimide, a polyamide or a liquid crystalline polymer.

9. The microelectronics package of claim 1, wherein the magnetic material of the solder mask has a relative magnetic permeability between 5 and 20.

10. The microelectronics package of claim 1, wherein the wherein the solder mask has a thickness between 15 microns and 30 microns.

11. A system, comprising:
a microelectronics package, comprising:
a substrate comprising a dielectric;
an inductor component comprising one or more wires within a magnetic core over the dielectric, wherein the inductor component is bonded to the substrate by one or more solder joints;
a solder mask between the inductor component and the dielectric, wherein the one or more solder joints are surrounded by the solder mask, and wherein the solder mask comprises a magnetic material; and
a die coupled to the substrate,
wherein the die comprises an integrated circuit that is coupled to the inductor.

12. The system of claim 11, wherein the die is a microprocessor die.

13. The system of claim 11, wherein the inductor comprises one or more wires extending within the magnetic core, and wherein the wires are substantially parallel to one another.

14. The system of claim 11, wherein the integrated circuit is an integrated voltage regulator.

15. The system of claim 14, wherein the integrated voltage regulator has any one of a buck converter topology, a boost converter topology, a buck/boost converter topology or a flyback converter topology.

16. A method, comprising:
forming a package substrate comprising dielectric and an array of bond pads on a surface of the substrate;
depositing a solder mask over the surface of the substrate, wherein the solder mask comprises a magnetic material;
depositing solder on the bond pads;
placing an inductor comprising a magnetic core over the surface of the substrate; and
reflowing the solder.

17. The method of claim 16, wherein placing an inductor comprising a magnetic core over the surface of the substrate comprises solder-bonding a magnetic inductor array (MIA) component to the package substrate, wherein the solder mask comprising a magnetic material is between the MIA component and the package substrate.

18. The method of claim 17, wherein the MIA component is attached to the land side of the package substrate, wherein the solder mask comprising a magnetic material is between the MIA component and the package substrate.

19. The method of claim 16, wherein the solder mask is in a layer that has a thickness ranging between 15 and 40 microns.

20. The method of claim 16, wherein the magnetic material comprises magnetic particles in a polymer matrix.
